(19) United States
(12) Patent Application Publication
(10) Pub. No.: US 2005/0231932 A1
(43) Pub. Date: Oct. 20, 2005

(54) Reinforcement for substrate assemblies

(75) Inventors: Marc N. Nestor, Lombard, IL (US); Mitch E. Goodman, Coral Springs, FL (US); Greg M. Gutierrez, Elgin, IL (US)

Correspondence Address: AKERMAN SENTERFITT, P.O. BOX 3188, WEST PALM BEACH, FL, 33402-3188, US

(73) Assignee: Motorola, Inc., Schaumburg, IL (US)

(21) Appl. No.: 10/826,953

(22) Filed: Apr. 15, 2004

(51) Int. Cl. H05K 9/00

(52) U.S. Cl. 361/818; 174/35 R

(57) ABSTRACT

The present invention is directed to a reinforced substrate apparatus (100) and method (600) for reinforcing a substrate (110). The substrate apparatus includes the substrate, a first shield (115, 215) coupled to the substrate and at least a second shield (120, 220) coupled to the substrate. A strengthening member (125, 225, 275) can be coupled to the first shield and the second shield without necessarily contacting the substrate. The method can include the step of attaching (620) the first shield and the second shield to the substrate where at least one among the first shield and the second shield shields circuitry on the substrate. The method also includes the step of coupling (640) a strengthening member to the first shield and the second shield.

### CROSS REFERENCE TO RELATED APPLICATIONS

Not Applicable.

### FIELD OF THE INVENTION

This invention relates generally to the field of substrate assemblies, and more particularly, to apparatus for reinforcing substrates.

### BACKGROUND

The different components of electronic devices, and in particular mobile electronic devices, must be able to withstand a variety of physical and environmental stresses. Many electronic devices include substrates which support circuitry. One common form of a substrate is a circuit board, such as a printed circuit board (“PCB”), which typically cannot accommodate appreciable flexing. Although PCB's are typically within a housing of the electronic device, the PCB can still experience stresses and strains in a variety of situations. For instance, many users of electronic devices, such as mobile phones, commonly drop their device. Such drops and other situations, whether intentional or unintentional, can cause mechanical strains and stresses on the PCB. Even relatively minor strains can cause catastrophic solder joint failure for some components attached to the PCB. Even a single solder joint failure can render an entire device inoperable, and with the ever decreasing size of electronic devices, such damage may be too costly or impractical to repair.

Manufacturers of electronic devices and substrates, such as PCB's, have attempted many different techniques and designs to reduce substrate strains. For instance, some electronic device housings have been designed to reduce substrate flexure and to reduce the overall strains that a substrate experiences. Nevertheless, changes to the housings can be expensive and limited in effect and can conflict with aesthetic concerns or other general design parameters. Still further, attempts have been made to increase the overall strength of the substrate by increasing the strength of the individual components attached to the substrate.

In one example, attempts have been made to increase the overall strength of a PCB by including a variety of materials in the PCB and/or soldering additional strengthening components directly to the PCB's. Nevertheless, soldering additional strengthening components directly to the PCB requires additional board space and may require a re-arrangement of the layout of the electrical circuit to a configuration that is less than optimal. Furthermore, soldering additional components directly to the PCB can require changes in the layout and geometries of the electromagnetic interference (“EMI”) shields that enclose different components attached to the PCB. Substantially altering the EMI shield geometries can be costly, may reduce the effectiveness of the EMI shield, and may also require the circuit layout to be less than optimal.

As electronic devices become increasing mobile, the physical and environmental stresses that such devices are exposed to must be addressed. At the same time, electronic devices are becoming increasingly smaller in size and the layout of associated substrates may not be able to be substantially altered to accommodate such stresses. Existing substrate assembly designs fail to produce an increase to the overall physical durability of electronic devices without compromising efficient electrical layouts and device size.

### SUMMARY OF THE INVENTION

A reinforced substrate apparatus or assembly and method for reinforcing a substrate can include the substrate, such as a printed circuit board, with greater durability without hindering performance. Further, the apparatus and method can be utilized with most current substrates and electronic devices. The apparatus and method do not require re-tooling and/or design changes to housings and also do not require any additional space on the substrate. The substrate is reinforced and stresses and strains are prevented from being localized as a strengthening member helps to distribute the stresses across the substrate. Accordingly, the apparatus and the method reduce stresses and strains with minimal cost impact while simultaneously allowing optimal layout of the electronic components and their current pathways.

In accordance with the inventive arrangements, a reinforced substrate apparatus can include a substrate, a first shield coupled to the substrate, and a strengthening member coupled to the first shield. The strengthening member can include at least one elongated member and the elongated member can be located between the first shield and a second shield. Further, the at least one elongated member can be orientated substantially perpendicular to a remaining portion of the strengthening member. Additionally, the apparatus can include at least the second shield where the strengthening member can be coupled to the first shield and the second shield.

In one embodiment, the strengthening member can be soldered to at least one among the first shield and the second shield. Also, the strengthening member can include a conductive material and the strengthening member can provide a ground current pathway between the first shield and the second shield.

In another arrangement, at least one of the first shield and the second shield can include a recessed surface and an un-recessed surface. In such an arrangement, a surface of the strengthening member can be at substantially the same height as the un-recessed shield surface when the strengthening member is attached to one or more of the first shield and the second shield within the recessed surface. Additionally, the strengthening member can be coupled to the first shield without contacting the substrate. Also, the substrate can be a substrate for a mobile electronic device.

In another aspect of the inventive arrangements, a reinforced substrate apparatus can be provided. The apparatus can include a substrate, a first shield coupled to the substrate, at least a second shield coupled to the substrate, and a strengthening member coupled to the first shield and the second shield without necessarily contacting the substrate. The strengthening member can include at least one elongated member which protrudes from the strengthening member and the elongated member can be located between the first shield and the second shield.

In yet another aspect of the inventive arrangements, a method for reinforcing a substrate is provided. The method can include the step of attaching a first shield and a second shield to the substrate where at least one among the first shield and the second shield shields circuitry on the substrate. The method can also include the step of coupling a strengthening member to the first shield and the second shield. Additionally, the method can include the steps of soldering the strengthening member to the first shield and the second shield. Alternatively, a first shield and the second shield can have a recessed portion or portions where the height of the recessed portion can be substantially equal to the thickness of the strengthening member. The recessed portion can be used for receiving and coupling the strengthening member to the first shield and the second shield.

The above features and advantages of the present invention will be better understood with reference to the following figures and detailed description. It should be appreciated that the particular devices and methods illustrating the embodiments of the present invention are merely exemplary and should not to be construed as limitations on the scope of the claimed invention.

### BRIEF DESCRIPTION OF THE DRAWINGS

There are presently shown in the drawings embodiments which are exemplary, it being understood, however, that the invention is not limited to the precise arrangements and instrumentalities shown.

FIG. 1 is a schematic drawing of one embodiment in accordance with the inventive arrangements.

FIG. 2 is an amplified view of a portion of the embodiment of FIG. 1.

FIG. 3 is another amplified view of a portion of the embodiment of FIG. 1.

FIG. 4 is a schematic drawing of another embodiment in accordance with the inventive arrangements.

FIG. 5 is a schematic drawing of yet another embodiment in accordance with the inventive arrangements.

FIG. 6 is a diagram illustrating the steps of a method of reinforcing a substrate.

### DETAILED DESCRIPTION

A reinforced substrate apparatus and method for reinforcing a substrate, such as a circuit board, do not necessarily require re-tooling and/or design changes to housings and also do not require any additional space on the substrate. As a result, the substrate is reinforced and stresses and strains are prevented from being localized as stresses are distributed across the substrate. In one embodiment, the stresses or strains can be distributed more evenly across the substrate.

In accordance with the inventive arrangements, one embodiment of the reinforced substrate apparatus 100 is shown in FIG. 1. The apparatus 100 can include a substrate 110, a first shield 115 coupled to the substrate 110, one or more second or additional shields 120 coupled to the substrate, and a strengthening member 125. The strengthening member 125 can be coupled to at least the first shield 115, and in other embodiments, to at least the second shield 120, to reinforce the substrate 110.

The substrate 110 can be any suitable substrate for use in a variety of devices, such as mobile phones, cordless phones, two way radios, pagers, personal digital assistants, laptop computers, and the like although the invention is not necessarily limited to such electronic or portable devices. As used herein, a substrate can include a sheet or layer of base material with or without an interconnection pattern and on which or within which discrete components Or integrated circuits (“IC's”) or both can be located. For example, a substrate can include a circuit board, a printed circuit board, and the like, and can be constructed of a variety of materials, such as metals, plastics, ceramics, and the like.

The first shield 115 and the second or additional shields 120 can be any sheet, screen, sheath, braid of metal, cover, or housing, that can reduce the propagation of electric, magnetic, or electromagnetic fields. The first and second shields 115 and 120 can be placed around or between electronic circuitry to contain any unintentional radiation leakage, or to prevent any unwanted interference. The shields can be constructed of any appropriate material, such as copper, aluminum, or any other conducting or non-conducting material as needed.

The apparatus 100 can include only a first shield 115 in which the first shield 115 provides adequate shielding for the different components or IC's located on the substrate 110. Thus, the first shield 115 can include a continuous sheet with one or more chambers for shielding individual components or IC's. Nevertheless, the apparatus 100 can include one or more second or additional shields 120 in addition to the first shield 115. As used herein, the second shield 120 can refer to one shield or multiple shields. The first shield 115 and the second shields 120 are not limited in size and/or shape and can be designed for any particular substrate and/or electronic device.

The strengthening member 125 can be used to reinforce the substrate 110. The strengthening member 125 can be any sheet, bar, or support structure that, when added to the apparatus 100, reinforces the apparatus 100. The strengthening member 125 can reinforce the apparatus 100 by increasing the overall strength of the substrate 110 and/or by decreasing the overall ability of the substrate 110 to flex. The strengthening member 125 can further reinforce the apparatus 100 by homogeneously distributing the stresses and strains across the substrate 110 to prevent localized concentrations. Thus, the strengthening member 125 can be constructed from a variety of metals, metal alloys, ceramics, plastics, composite materials, and the like.

As shown in the figures, the strengthening member 125 can be coupled to both the first shield 115 and the (one or more) second shield 120, but it should be noted that the strengthening member 125 can be coupled solely to the first shield 115 to reinforce the substrate 1110. Also, the strengthening member 125 can include a variety of geometries that can couple to one or more shields 115 and 120. The strengthening member 125 can be coupled to the shields 115 and 120 through a variety of mechanical and chemical attachments. For instance, when the strengthening member 125 is constructed of an appropriate material, such as a metal alloy, the strengthening member 125 can be soldered to the shields 115 and 120. Nevertheless, the invention is not limited in this regard as the strengthening member 125 can be coupled to the shields 115 and 120 with adhesives such as epoxy. Additionally, the strengthening member 125 and the corresponding shields 115 and 120 can include corresponding engagement structures so that the strengthening member 125 can be inserted into the shield engagement structures and locked into an engaged position. The engagement structures can be in the form of a recessed surface and or slot or slots enabling the insertion of the strengthening member by a press-fit or snap-fit.

Still further, the strengthening member 125 and the shields 115 and 120 can alternatively be made of a continuous construction (not shown). For instance, the strengthening member 125 can be a support for a unified structure comprised of shields 115 and 120 in an integrated form made of stamped sheet metal for example. Accordingly, in such a configuration, the multiple shields and the strengthening member 125 can be considered a unitary construction where the multiple shields are considered only a single shield.

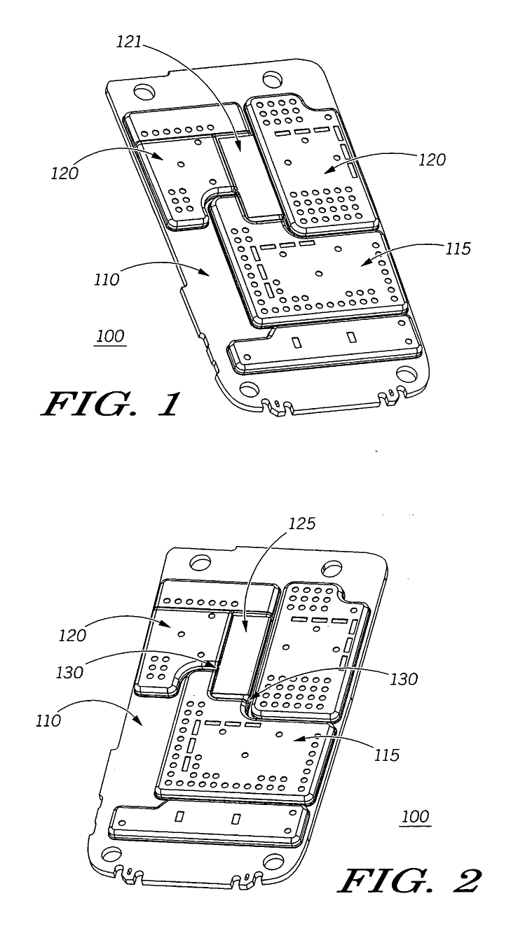

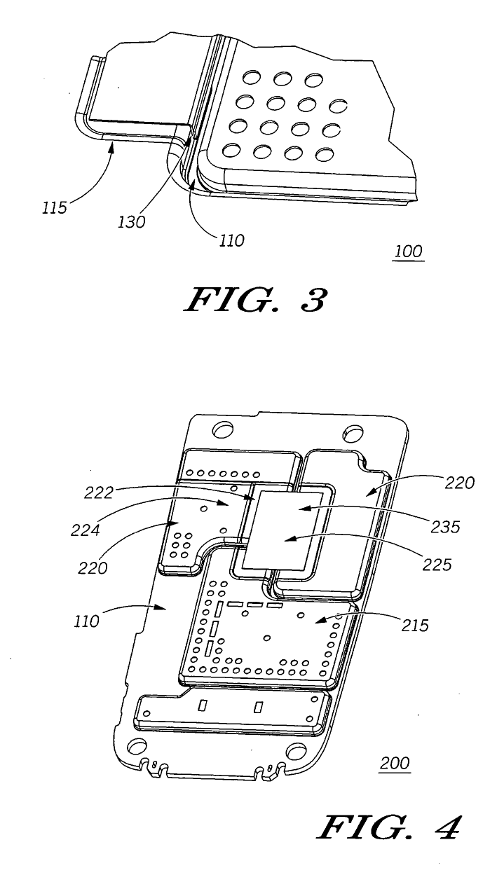

In one arrangement as shown more clearly in FIGS. 2 and 3, the strengthening member 125 can provide further reinforcing features by providing a protruding elongated member 130. The protruding elongated member 130 can be an integrated extension of the strengthening member 125 or alternatively a coupled extension to the strengthening member 125. For instance, as shown in FIG. 3, the elongated member 130 can be strain hardened to be able to withstand even greater stresses and strains. Strain hardening can include the application of cold work after annealing (or after hot forming), or can include a combination of cold work and partial annealing or stabilizing, in order to secure the specified mechanical properties. As shown in this embodiment, the strengthening member 125 including the elongated member 130 form an “L” shaped bracket.

The elongated member 130 can be orientated to reinforce against likely user-induced forces which could cause a flexion in the substrate 110. During a typical use, a user may be more likely to induce particular stresses based on the shape of the substrate and the device housing. Furthermore, accidental drops may induce predictable stresses and strains along various axes of the substrate. For example, a typical substrate 110 may experience stresses which could cause flexion, and if strong enough, would cause a folding in the substrate 110 along an imaginary line or region. The elongated member 130 can be orientated generally perpendicular to the imaginary line or region to prevent the flexion. Further, multiple elongated members 130 can be included to reinforce against forces at a variety of points along the substrate 110. Multiple elongated members 130 can generally be orientated in a non-parallel fashion with each other (or with a remaining portion of their respective strengthening members) to provide a greater amount of reinforcement. It is understood, however, that the elongated member 130 is not necessary, as the strengthening member 125 by itself can provide an adequate amount of reinforcement.

Additionally, the elongated member 130 can be orientated between the first shield 115 and the second shield 120. Such a design allows not only for compact configuration, but can also provide further reinforcement. In this arrangement, the elongated member 130 can function as a wedge between adjacent shields 115 and 120 to prevent the shields from being compressed together. Although the elongated member 130 can extend between the shields 115 and 120 towards the substrate 110, it should be noted that the elongated member 130 does not necessarily come into contact with the substrate 110. Accordingly, the strengthening member 125 can reinforce the substrate 110 without directly contacting the substrate 110.

Referring to FIGS. 4 and 5, substrate assemblies 200 and 300 are shown respectively. It should be noted that a strengthening member 225 or 275 can be included without increasing the overall thickness of a substrate 110 combined with shields 215 and 220. Shield 215 or shields 215 and 220 can include a recessed surface or stepped down area, at which the height of the shield is decreased so that there is less distance to the substrate from the recessed surface. Accordingly, such a shield 220 will have at least two surfaces with two different heights, a recessed surface 222 and an un-recessed surface 224. In such a configuration, the strengthening member 225 can be designed, so that when coupled to the shields 215 and 220, a surface 235 of the strengthening member 225 (or 275) is substantially at the same height or plane as the un-recessed surface 224. Thus, the strengthening member 225 or 275 can be added to conventional substrates having shields with only minor recessed adjustments to shields and not affect the overall thickness of the combined substrate and shields. For example, the height of the strengthening member 225 or 275 can be substantially the same height or less than the distance between the recessed surface 222 and the un-recessed surface 224. Of course, those of ordinary skill the art will appreciate that the strengthening member and the surface of the shield do not necessarily need to be substantially at the same height or plane.

Referring once again to FIGS. 4 and 5, note that the assemblies 200 and 300 differ in that different strengthening members are used. The strengthening member 225 of assembly 200 of FIG. 4 does not include an elongated member and can merely be a flat member that couples the three shields (215, 220 and 220) together as shown. Once again, the strengthening member 225 can be coupled to a top surface of the shields or alternatively if the shields include a recessed area, the strengthening member can be placed in such recessed area (222). In the embodiment of FIG. 5, the strengthening member 275 of assembly 300 can either be a unitary piece having an elongated member 230 or alternatively the strengthening member 275 can be two separate pieces have two corresponding elongated members 230. If the strengthening member 275 is unitary, then it couples all three shields (215, 220 and 220) as shown. If the strengthening member 275 is two separate members, then the left member of 275 couples the left shield 220 to the shield 215 while the right member of 275 can reinforces the right shield 220.

Further, it should be noted that the strengthening member 225 or 275 can be constructed of a conductive material, and therefore, can provide a ground current pathway between the first shield 215 and the second shield 220. As well known, the shields 215 and 220 can be connected to a ground or a point of zero potential. By coupling a conductive strengthening member 225 or 275 between shields 215 and 220, electrical currents can be grounded at any of the various ground points electrically coupled to shields 215 and 220. This arrangement allows for the design layout of the electrical pathways and connections of the substrate to be unrestricted by the need to contact shields directly with the ground. Such freedom of shield placement can help design more optimal layouts of substrates.

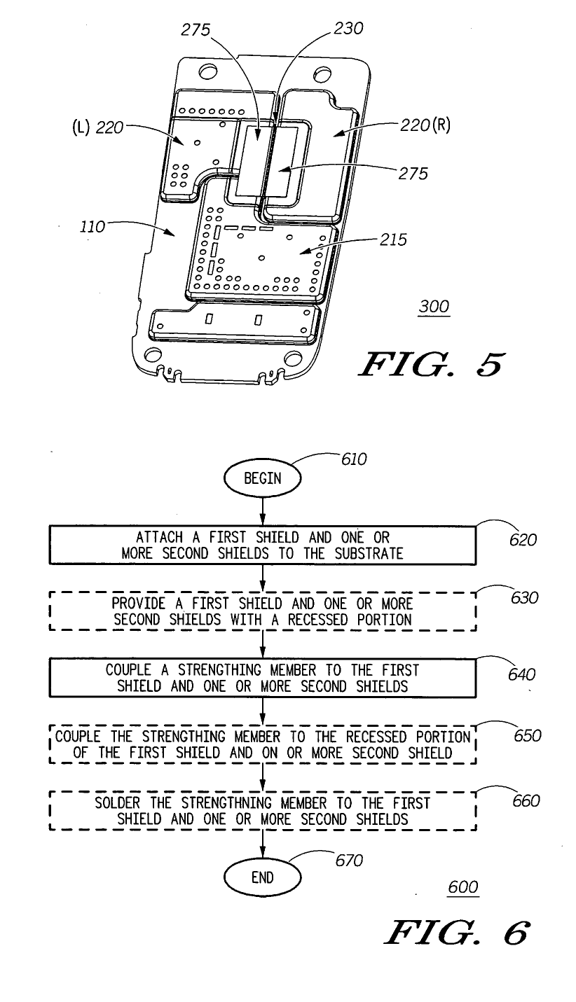

Referring to FIG. 6, a flow chart illustrating a method 600 for reinforcing a substrate is shown in accordance with the inventive arrangements. Although the method 600 can be used with the apparatus as described above, the invention is not limited in this regard. Also, it should be noted that some steps of the method 600 are not necessary and that additional steps can be added.

The method can begin at step 610. In step 620, a first shield and one or more second shields can be attached to a substrate. The shields can be attached using any particular process which is well known in the art such as soldering or using adhesives. It should be noted that the method is not limited to a particular arrangement of the shields.

In some arrangements, the method 600 can include the step 630 of providing the first shield and the one or more second shields with recessed portions. Such shields can have a lower height and can allow for the addition of a strengthening member without adding to the overall thickness of the combined substrate and shields.

With the shields attached to the substrate, the strengthening member can be coupled to the first shield and the second shield in step 640. Note, the method 600 is not limited to the order shown. For example, the shields can be coupled together using the strengthening member and then attached to the substrate. The strengthening member can be coupled with a variety of attachments, including both mechanical and chemical attachments. For example, the strengthening member can be attached with an adhesive. More particularly, the strengthening member can be soldered to the shields in step 660.

Alternatively, it should be noted that in a configuration where shields are provided with recessed shields, the strengthening member can be coupled (snap-fit, press-fit, adhered, etc.) to the recessed portion in step 650. When coupled to the recessed portions, the top surface of the strengthening member can be in substantially the same plane as or beneath the top surface of the shield. Such an arrangement does not produce any increase in thickness if desired. Consequently, the housing in which the substrate is located does not need any redesigning. The method 600 can end at step 670 or any of the steps can be repeated.

This invention can be embodied in other forms without departing from the spirit or essential attributes thereof. Accordingly, reference should be made to the following claims, rather than to the foregoing specification, as indicating the scope of the invention.

1. A reinforced substrate apparatus, comprising:
a substrate;
a first shield coupled to the substrate; and
a strengthening member coupled to the first shield.

2. The apparatus according to claim 1, wherein the strengthening member includes at least one elongated member.

3. The apparatus according to claim 1, further comprising at least a second shield, wherein the strengthening member is coupled to the first shield and the second shield.

4. The apparatus according to claim 3, wherein the strengthening member is soldered to at least one among the first shield and the second shield.

5. The apparatus according to claim 3, wherein the strengthening member includes a conductive material.

6. The apparatus according to claim 5, wherein the strengthening member provides a ground current pathway between the first shield and the second shield.

7. The apparatus according to claim 3, wherein the strengthening member includes at least one elongated member.

8. The apparatus according to clam 7, wherein the at least one elongated member is located between the first shield and the second shield.

9. The apparatus according to claim 7, wherein the at least one elongated member is orientated non-parallel with another elongated member.

10. The apparatus according to claim 3, wherein at least one of the first shield and the second shield includes a recessed surface and an un-recessed surface, a surface of the strengthening member is at substantially the same height as the un-recessed surface when the strengthening member is attached to at least one of the first shield and second shield within the recessed surface.

11. The apparatus according to claim 1, wherein the substrate is a substrate for a mobile electronic device.

12. The apparatus according to claim 1, wherein the strengthening member is coupled to at least the first shield without contacting the substrate.

13. A reinforced substrate apparatus, comprising:
a substrate;
a first shield coupled to the substrate;
at least a second shield-coupled to the substrate; and
a strengthening member coupled to the first shield and at least the second shield.

14. The apparatus according to claim 13, wherein the strengthening member includes at least one elongated member protruding from the strengthening member.

15. The apparatus according to clam 14, wherein the elongated member is located between the first shield and the second shield without contacting the substrate.

16. The apparatus according to claim 13, wherein the reinforced substrate apparatus is a substrate for a mobile electronic device and the first shield and the second shield reduce electromagnetic interference.

17. A method of reinforcing a substrate, comprising the steps of:
attaching a first shield and at least a second shield to the substrate, wherein at least one among the first shield and the second shield shields circuitry on the substrate; and
coupling a strengthening member to the first shield and the second shield.

18. The method according to claim 17, further comprising the step of:
soldering the strengthening member to at least one among the first shield and the second shield.

19. The method according to claim 17, further comprising the step of:
providing a first shield and the second shield with a recessed portion, wherein the height of the recessed portion is substantially equal to the thickness of the strengthening member.

20. The method according to claim 17, wherein the first shield and the second shield comprise a recessed portion for receiving and coupling the strengthening member to the first shield and the second shield.
